(19) United States
(12) Patent Application Publication
(10) Pub. No.: US 2020/0303584 A1
(43) Pub. Date: Sep. 24, 2020

(54) Method for Producing a Nitrogen-Free Layer Comprising Silicon Carbide

(71) Applicant: PSC Technologies GmbH, Berlin (DE)

(72) Inventor: Siegmund GREULICH-WEBER, Bad Lippspringe (DE)

(73) Assignee: PSC Technologies GmbH, Berlin (DE)

(21) Appl. No.: 16/651,384

(22) PCT Filed: Sep. 20, 2018
(86) PCT No.: PCT/EP2018/075493

§ 371 Date: Mar. 27, 2020

(30) Foreign Application Priority Data
Sep. 27, 2017 (DE) 102017122708.3

(51) Int. Cl. H01L 31/18; H01L 21/02; H01L 21/324; H01L 29/16; H01L 31/028

(52) U.S. Cl. CPC H01L 31/1804; H01L 21/02529; H01L 31/028; H01L 29/1608; H01L 21/324

(57) ABSTRACT

The present invention relates to a method for producing a thin nitrogen-free layer of silicon carbide by means of a carbon- and silicon-containing solution or dispersion.

The present invention relates to the technical field of semiconductor technology. In particular, the present invention relates to a process for producing a silicon carbide-containing layer, the layer being nitrogen-free. Furthermore, the invention relates to a silicon carbide (SiC) layer and the use of a silicon carbide layer within a solar cell. Furthermore, the invention relates to a process for producing a solar cell and a solar cell.

In times of climate change, regenerative energies and/or regenerative types of conversion to mechanical and/or electrical and/or chemical energy are becoming increasingly important. There is great potential here in the field of photovoltaics. For a long time, research and/or industry has assumed a maximum efficiency of about 30% to 40%, depending on the material used and the design of the solar cell. Due to the small band gap of silicon, however, the thermalization problem caused by higher energy radiation from the sun cannot be avoided. Thus, all photons that have a higher energy than the band gap contribute to the higher energetic radiation and thus limit the theoretically maximum possible efficiency of a solar cell.

This maximum efficiency is also known as the Shockley-Queisser limit. Shockley and Queisser have determined an upper, maximum limit for the efficiency, i.e. the utilization of the available energy of the sun, of about 30%, in particular taking into account unfocused sunlight outside the earth's atmosphere.

In research there have been investigations or different research approaches in recent years and decades with regard to increasing the maximum efficiency to be achieved. In summary, the different trends and approaches can be described under the term “third generation solar cells”. For so-called “third generation solar cells”, a maximum efficiency of 86% is assumed. This efficiency is based on the Carnot efficiency, taking into account the temperature of the sun and the usable proportion of the irradiated solar radiation, determined by the Boltzmann law. Ultimately, the theoretical maximum possible Carnot efficiency cannot be achieved in practice with the usable portion of the radiation power in a commercial photovoltaic application in the form of a solar cell. The starting point is, however, that the previously assumed efficiency, which is limited due to semiconductor technology, can be increased.

Under the generic term “solar cells of the third generation”, various approaches to optimizing the efficiency are bundled, which attempt to reduce thermalization losses. Most of these approaches—with the exception of the tandem solar cell—are theoretical concepts and models that have not yet been implemented or demonstrated. An example of this is the thermophotovoltaic conversion, in which an intermediate absorber is heated by solar radiation and the absorber on the back of a solar cell absorbs part of the thermal radiation from the intermediate absorber and converts it into electrical energy. With tandem cells, on the other hand, it is possible to operate a solar cell with monochromatic radiation, whereby a plurality of solar cells are arranged one behind the other with a decreasing energy gap. In the concept of up- and down-conversion it is planned to adapt the solar spectrum to the solar cell material by means of a luminescent material.

A further research direction for third-generation solar cells can be seen in the “intermediate band solar cells”, which use the “Impurity Photovoltaic (IPV) Effect”. By using an “intermediate” band (IB) as a so-called intermediate band between the conduction and valence band, photons with an energy lower than the band gap can be used. Photons with an energy lower than the band gap between the conduction band and the valence band would otherwise be transmitted unused. Accordingly, both the induced photocurrent and the efficiency of the solar cell can be increased. It is therefore possible to generate additional electron-hole pairs via the intermediate band or the intermediate energy level, although recombining an electron-hole pair via the intermediate state is also possible.

In the field of intermediate band solar cells, materials can be used which, due to their large band gap, have not yet been considered for use within a solar cell. With a large band gap, the problem of thermalization described above can be avoided, but the maximum efficiency for conventional solar cells also drops significantly at band gaps above 2 eV, so that band gaps above 2 eV, which are not subject to thermalization problems, were not considered. The maximum possible efficiency is highest for a conventional solar cell after the Schockley-Queisser limit at a band gap between 1 eV and 2 eV.

The choice of material for the suitable implementation of an IB solar cell is difficult, as a large number of different factors must be taken into account. Despite the promising theoretical approach of intermediate band solar cells, these are not yet available. Only theoretical possible material compositions in the state of the art were discussed.

For example, it was considered that IB solar cells are based on new nanomaterials using quantum dots. Furthermore, it is known to perform impurity doping or to use low-alloy semiconductor alloys. The impurity doping is difficult due to the unwanted recombination via the recombination channel caused by the impurities. With the quantum dots, the basic concept of an intermediate band solar cell could be demonstrated, whereby the intermediate band can increase the efficiency of the solar cell. In addition, gallium arsenide (GaAs) is used as host material for the aforementioned systems, whereby the band gap energy of 1.42 eV is considerably lower than the optimal band gap energy for an intermediate band solar cell with 2.4 eV. Low alloy semiconductor alloys may also include InGaAsN and ZnTe:O, where the energy level of the intermediate band may be variable by the alloy composition. The above approaches are currently being scientifically discussed and investigated.

Furthermore, cubic silicon carbide (3C-SiC) has been considered as a material within the research area “Third Generation Solar Cells”. Theoretically, the bandgap of 3C-SiC would be suitable for use in the intermediate-band solar cell, although the current state of the art does not provide any concrete proposals for the production of such a solar cell. The doping of 3C-SiC with boron enables an energy level of 0.7 eV above the valence band. This energy level can be used within the intermediate band solar cell. However, 3C-SiC could not be used in a layer structure of the intermediate band solar cell, especially for large-scale industrial implementation. The fundamental feasibility of 3C-SiC intermediate band solar cells was scientifically discussed in the state of the art. In particular, impurity doping within a layer was investigated, see for example Syvajarvi et al., “Cubic silicon carbide as a potential photovoltaic material”, 2016, Solar Energy Materials and Solar Cells, (145), 104-108. In addition, Sun et al. could show in “Solar driven energy conversion applications based on 3C-SiC”, 2016, Materials Science Forum, 1028-1031, that 3C-SiC is a promising material for application within an intermediate band solar cell.

However, as previously stated, the state of the art lacks the actual implementation of an intermediate band solar cell with an increased efficiency, in particular when using a host material based on 3C-SiC. The theoretical basic suitability of the doped 3C-SiC material is still far from the actual production of a solar cell of the aforementioned type.

The deposition of doped 3C-SiC layers on a carrier surface or on a substrate for the production of a solar cell is associated with problems that cannot be overcome with the known methods of depositing layers for the production of a solar cell. The biggest challenge in the production of intermediate band solar cells is the realization of the photovoltaic behavior.

A lack of knowledge of the manufacturing process for a silicon carbide solar cell is also due to the fact that silicon carbide is an unsuitable material for a conventional solar cell. The band gap of 2.3 eV was considered too large for conventional solar cells, as explained above. With a band gap greater than 2 eV, the maximum efficiency for 3C-SiC in the range of a conventional solar cell is significantly lower than for silicon, for example.

In addition, with regard to a 3C-SiC intermediate band solar cell, research into a 3C-SiC intermediate band solar cell is hindered by excessively high prices for SiC monocrystal production, insufficiently large usable areas of the SiC wafers currently in use, problems in the production of the 3C-SiC material and the necessity for the SiC wafer to be free of nitrogen, all of which stand in the way of realizing the usable product, i.e. the actually produced intermediate band solar cell. By using standard crystallization processes, 3C-SiC can only be produced with difficulty or at very great expense. As a result, the minimum area required for a solar cell cannot be produced using the methods known from the state of the art. The wafers available for the production of a solar cell are also much too small.

A further problem arises from the fact that commercially available silicon carbide is inevitably contaminated with nitrogen. Nitrogen is the shallow donor in silicon carbide and therefore electrically active. To obtain a semi-insulating silicon carbide, the nitrogen is usually passivated with boron. Boron is the acceptor in the 3C-SiC. Consequently, the silicon carbide contains the boron acceptor and the nitrogen donor by volume. However, under solar radiation this leads to an intensive and fast donor-acceptor recombination luminescence. This recombination luminescence represents an effective short circuit for a solar cell and should therefore be avoided at all costs.

So far, no commercially usable intermediate-band solar cells could be provided in the state of the art, in particular no commercially usable intermediate-band solar cells using 3C-SiC.

The object of the present invention is now to avoid or at least substantially reduce and/or mitigate the disadvantages and problems described above in the state of the art.

In particular, it is an objective of the present invention to provide a method for producing a silicon carbide-containing layer, whereby the method is intended to ensure that the layer is at least substantially free of nitrogen.

Subject matter of the present invention—according to a first aspect of the present invention—is a method for producing a silicon carbide-containing layer according to claim 1; further, advantageous embodiments of this aspect of the invention are subject matter of the respective dependent claims.

Further subject-matter of the present invention—according to a second aspect of the present invention—is a silicon carbide (SiC) layer according to claim 13.

Furthermore, a subject matter of the present invention—according to a third aspect of the present invention—is a method for producing a solar cell according to claim 15; further advantageous embodiments of this aspect of the invention are subject matter of the respective dependent claims.

Finally, another subject matter of the present invention—according to a fourth aspect of the present invention—is a solar cell according to claim 20.

It goes without saying that the particular features mentioned in the following, in particular special embodiments or the like, which are only described in relation to one aspect of the invention, also apply in relation to the other aspects of the invention, without this requiring any express mention.

Furthermore, for all relative or percentage, in particular weight-related, quantities or amounts stated below, it is to be noted that, within the framework of this invention, these are to be selected by the person skilled in the art in such a way that the sum of the ingredients, additives or auxiliary substances or the like always results in 100 percent or 100 percent by weight. This, however, goes without saying for the person skilled in the art.

In addition, the skilled person may deviate from the values, ranges or quantities listed below, depending on the application and individual case, without leaving the scope of this invention.

In addition, all of the parameters specified below or the like can be determined by standardized or explicitly specified determination methods or by common determination methods known per se by the person skilled in the art.

With this provision made, the subject-matter of the present invention is explained in more detail in the following.

Subject matter of the present invention—according to a first aspect of the present invention—is thus a method for producing a silicon carbide-containing layer, the layer being nitrogen-free, wherein
(a) in a first method step, a liquid carbon- and silicon-containing solution or dispersion, in particular a SiC precursorsol, is applied to a carrier
(b) in a second method step following the first method step (a), the carbon- and silicon-containing solution or dispersion, in particular the SiC persecursol, is converted to silicon carbide, wherein the carbon- and silicon-containing solution or dispersion is subjected to a multi-stage thermal treatment, wherein
   (i) in a first thermal process stage (i) the carbon- and silicon-containing solution or dispersion, in particular the SiC precursorsol, is heated to temperatures of 300° C. or higher, in particular 300 to 1800° C., preferably 800 to 1000° C., and
   (ii) in a second thermal process stage following the first thermal process stage (i), the carbon- and silicon-containing solution or dispersion, in particular the SiC precursorsol, is heated to temperatures of 1800° C. or higher, in particular 1800 to 2200° C.

In the context of the present invention, a “nitrogen-free” layer is understood to be a layer which at least substantially does not contain nitrogen. Also, in the context of the present invention, a “completely nitrogen-free” layer is understood to be a layer which at least substantially does not contain nitrogen. In principle, however, it is possible that individual nitrogen atoms are still present in the layer, wherein this small amount of nitrogen is not sufficient for the layer to exhibit the properties of a nitrogen-containing layer. In particular, the nitrogen-free layer is configured in such a way that it exhibits the properties of a nitrogen-free layer. Accordingly, there is no longer any influence of nitrogen on the layer. Consequently, the statement that the layer is nitrogen-free does not refer to an atomic level or an atomic scale, but the statement indicates that the layer is not influenced by nitrogen in any way.

As the applicant surprisingly found out, the nitrogen-containing compounds are decomposed and transferred to the gas phase during heating to at least substantially 1000° C. for preferably 15 to 60 minutes, in particular wherein nitrogen is present as elemental nitrogen or volatile nitrogen compound.

According to a preferred embodiment of the present invention, the layer comprising silicon carbide consists of optionally doped silicon carbide, i.e. the layer comprising silicon carbide is an optionally doped silicon carbide layer.

The applicant found that a silicon carbide-containing nitrogen-free layer can be produced by a carbon- and silicon-containing solution or dispersion, wherein the latter has an extremely small number of defects and the layer is therefore excellently suited for semi-conductor applications.

In addition, according to the method of the invention, the layers of silicon carbide that are nitrogen-free can be produced on a wide variety of carriers, rather than only on monocrystalline substrates such as silicon carbide or silicon wafers. In particular, in the context of the present invention, it is also possible to remove the support after the silicon carbide layer has been produced. Ultimately, the carrier serves for the arrangement or deposit of the layer, provided that the layer has not yet been cured or heattreated.

The method according to the invention enables the simple, cost-effective and reproducible production of nitrogen-free layers of silicon carbide or silicon carbide bodies with a flat surface.

By means of an at least two-stage thermal treatment in method step (b), the carbon- and silicon-containing solution or dispersion is converted particularly gently and completely into monocrystalline silicon carbide, which has only an extremely small number of defects.

In the context of the present invention, a carbon- and silicon-containing solution and dispersion means a solution or dispersion, in particular a precursorsol, which contains carbon- and silicon-containing chemical compounds, wherein the individual compounds may contain carbon and/or silicon. Preferably the carbon and silicon-containing compounds are suitable as precursorsol for the target compounds to be prepared.

In the context of the present invention, a precursor is understood to be a chemical compound or a mixture of chemical compounds which react by chemical reaction and/or under the influence of energy to form one or more target compounds.

In the context of the present invention, a precursorsol is understood to be a solution or dispersion of precursor substances, in particular starting compounds, preferably precursors, which react to the desired target compounds. In the precursorsols, the chemical compounds or mixtures of chemical compounds are no longer necessarily present in the form of the originally used chemical compounds, but rather, for example, as hydrolysis, condensation or other reaction or intermediate products. This is, however, also made particularly clear by the expression “sol”. Within the scope of sol-gel processes, inorganic materials are usually converted under hydro- or solvolysis into reactive intermediates or agglomerates and particles, the so-called sol, which subsequently age to a gel, particularly through condensation reactions, wherein larger particles and agglomerates are formed in the solution or dispersion.

In the context of the present invention, a SiC precursorsol is understood to be a sol, in particular a solution or dispersion, which contains chemical compounds or their reaction products, from which silicon carbide can be obtained under processing conditions.

In the context of the present invention, a solution is to be understood as a usually liquid single-phase system in which at least one substance, in particular a compound or its components, such as for example ions, are homogeneously distributed in a further substance, the so-called solvent. In the context of the present invention, a dispersion is to be understood as an at least two-phase system, a first phase, namely the dispersed phase, being distributed in a second phase, the continuous phase. The continuous phase is also referred to as dispersion medium or dispersant; the continuous phase is usually present in the present invention in the form of a liquid and dispersions are generally solid-in-liquid dispersions in the present invention. However, in particular with sols or also with polymeric compounds, the transition from a solution to a dispersion is often fluid and it is no longer possible to distinguish clearly between a solution and a dispersion.

In the context of the present invention, a layer means the distribution of material, in particular in the form of a monocrystal, with a certain layer thickness in one plane, in particular on a surface of a carrier or substrate. The plane need not be completely covered with the material. Usually, however, at least one surface of the carrier or substrate is completely covered with the layer of silicon carbide or with a layer of the carbon- and silicon-containing solution or dispersion.

In the context of the present invention, a carrier is understood to be the material to which the carbon- and silicon-containing solution or dispersion, in particular the SiC precursorsol, is applied. In particular, in the context of the present invention, a carrier is a three-dimensional or almost two-dimensional structure with at least one preferably flat surface to which the carbon- and silicon-containing solution or dispersion is applied. The carrier is thus preferably a carrier material for producing the layer of silicon carbide from the formless carbon- and silicon-containing solution.

The silicon carbide produced in the context of the present invention is, as previously stated, either doped silicon carbide or undoped silicon carbide, the silicon carbide preferably being in monocrystalline form. Monocrystals are particularly suitable for use in semiconductor technology.

In the context of the present invention it is generally intended that in the first method step (a) the carbon- and silicon-containing solution or dispersion, in particular the SiC precursorsol, is applied as a layer, in particular as a homogeneous layer, to the carrier. By applying the carbon- and silicon-containing solution or dispersion, in particular the SiC precursorsol, in the form of a layer on the carrier, homogeneous monocrystalline layers of silicon carbide can be obtained.

Usually, in the first thermal process stage (i) the carbon- and silicon-containing solution or dispersion, in particular the SiC precursorsol, is transferred into a glass. The heating in the first thermal process stage removes in particular the solvents, dispersants and other volatile substances and pyrolyzes the non-volatile components of the carbon- and silicon-containing solutions or dispersions. In the pyrolysis process, preferably a glass remains, in which preferably silicon and carbon are present in high concentration. In the context of the present invention, a glass is to be understood as an amorphous solid body which has a near but not a far order. A glass is in particular a solidified melt.

With regard to the period of time in which the carbon- and silicon-containing solution or dispersion, in particular the SiC precursorsol, is heated in process stage (i), this can naturally vary over a wide range. However, in the context of the present invention, it has proved to be effective in the first thermal process stage (i) if the carbon- and silicon-containing solution or dispersion, in particular the SiC precursorsol, is heated for a period of at least substantially 5 to 150 minutes, preferably 10 to 120 minutes, preferably 15 to 60 minutes.

The aforementioned period of time makes it possible to ensure a nitrogen-free layer during pyrolysis and crystallization to silicon carbide. During this process, the nitrogen-containing compounds are decomposed and transferred to the gas phase. The aforementioned period of preferably about 30 minutes ensures that at least substantially all relevant nitrogen-containing compounds have also been decomposed, so that the layer comprising silicon carbide obtained by the thermal treatment has the properties of a completely nitrogen-free layer.

As far as the period of time is concerned, for which the carbon- and silicon-containing solution or dispersion, in particular the glass obtained in process stage (i), is heated in the second process stage (ii), this can vary in a wide range. Usually, in process stage (ii) the carbon- and silicon-containing solution or dispersion, in particular the SiC precursorsol, preferably the glass obtained in process stage (i), is heated for a period of more than 10 minutes, in particular more than 15 minutes, preferably more than 20 minutes, more preferably more than 25 minutes.

Similarly, it may be provided in the context of the present invention that in process stage (ii) the carbon- and silicon-containing solution or dispersion, in particular the SiC precursorsol, preferably the glass obtained in process stage (i), is heated for a period of 10 to 90 minutes, in particular 10 to 40 minutes, preferably 20 to 35 minutes, more preferably 25 to 40 minutes, particularly preferably at least substantially 40 minutes. The aforementioned periods are sufficient to obtain complete conversion of the precursors into silicon carbide and formation of silicon carbide monocrystals, but are sufficiently short to prevent excessive sublimation of silicon carbide.

In a preferred embodiment of the present invention, in a process stage preceding the first thermal process stage (i), the carbon- and silicon-containing solution or dispersion, in particular the SiC precursorsol, is heated to temperatures in the range from 50 to 800° C., in particular 100 to 500° C., preferably 100 to 250° C. As far as the time period for heating is concerned, it has been found to be particularly advantageous if the drying stage preceding the first thermal process stage (i) is carried out for at least substantially 5 to 30 minutes, preferably 5 to 20 minutes, more preferably 10 to 18 minutes, particularly preferably at least substantially 15 minutes. The aforementioned period as well as the aforementioned temperature ranges serve to dry the material before it is subjected to the thermal treatment in process stages (i) and (ii).

According to another particularly preferred embodiment, the nitrogenous compounds of the carbon- and silicon-containing solution or dispersion have been decomposed by the thermal treatment, in particular in the first thermal process stage (i). Thereby, the nitrogen-containing compounds may have been transferred into the gas phase, wherein the nitrogen can be transferred into the gas phase in the form of elementary nitrogen or volatile nitrogen-containing compounds. By decomposing the nitrogen-containing compounds, a nitrogen-free layer can be ensured, whose material properties, unaffected by nitrogen, are particularly advantageous in connection with semiconductor applications.

Usually in process stage (ii) the carbon- and silicon-containing solution or dispersion, in particular the SiC precursorsol, preferably the glass obtained in process stage (i), is converted into crystalline silicon carbide, preferably monocrystalline silicon carbide.

In the context of the present invention, it has proven to be advantageous if in the first thermal process stage (i) the carbon- and silicon-containing solution or dispersion is pyrolyzed and converted into a glass and in a subsequent separate process stage, in particular in the second thermal process stage (ii), the crystallization and production of the silicon carbide monocrystals takes place. In this way, particularly pure silicon carbide monocrystals with small proportions of defect structures can be obtained. In particular, it is possible to adjust the polytype of the silicon carbide by appropriate temperature selection during the second thermal process stage (ii). For example, at a temperature of 1800° C. in the second thermal process stage (ii) the polytype 3C-SiC is obtained, and at temperatures above 2100° C. in the second thermal process stage (ii) the hexagonal SiC polytypes, namely 4H—SiC and 6H—SiC, are obtained.

According to a preferred embodiment of the present invention, it may be provided that following process stage (i) and before carrying out process stage (ii), the carbon- and silicon-containing solution or dispersion, in particular the SiC precursorsol, preferably the glass obtained in process stage (i), is cooled, in particular quenched. By cooling, in particular quenching the glass obtained, the amorphous glass state is obtained and/or frozen. In particular, in this way it is possible to obtain an ideal starting condition for the subsequent conversion to monocrystalline silicon carbide.

As far as the cooling rate is concerned in this context, this can naturally vary within a wide range.

However, in the context of the present invention, it has proven to be effective if the carbon- and silicon-containing solution or dispersion, in particular the SiC precursorsol, preferably the glass obtained in process stage (i), is cooled at a cooling rate of more than 50° C./min, in particular more than 70° C./min, preferably more than 100° C./min.

Usually, in the context of the present invention, at least process stages (i) and (ii) are carried out in a protective gas atmosphere, in particular an inert gas atmosphere. According to a preferred embodiment of the present invention, in particular the entire method step (b) is carried out in a protective gas atmosphere, in particular an inert gas atmosphere, wherein it is particularly preferred if both method steps (a) and (b) are carried out in a protective gas atmosphere, in particular an inert gas atmosphere.

In the context of the present invention, an inert gas is understood to be a gas which effectively prevents oxidation of the components of the carbon- and silicon-containing solution or dispersion by oxygen in particular, while an inert gas in the context of the present invention is a gas which does not react with the components of the carbon- and silicon-containing solution or dispersion under process conditions. In the context of the present invention, the protective gas is usually selected from noble gases and mixtures thereof, in particular argon and mixtures thereof. In the context of the present invention, it is particularly preferred if the protective gas is argon.

Preferably, the silicon-carbide layer is doped. As a result, the layer may contain doped silicon carbide, the silicon carbide preferably being in monocrystalline form. Both a monocrystalline form and the properties of the layer unaffected by nitrogen are suitable for use in semiconductor technology.

A doped silicon carbide is a silicon carbide which is doped with further elements, in particular from the 13th and 15th group of the periodic table of the elements, in small quantities. Preferably, the silicon carbide has at least one doping element in the ppm (parts per million) or ppb (parts per billion) range. In particular, the layer containing silicon carbide is p-doped, or defects or grid gaps are selectively inserted. The doping of the silicon carbides has a particularly decisive influence on the electrical properties of the silicon carbides, so that doped silicon carbides are particularly suitable for applications in semiconductor technology, preferably in the area of solar cells. Dopings with doping elements that have more than four valence electrons are called n-dopants, while dopings with doping elements that have less than four valence electrons are called p-dopants. As mentioned before, p-doping of the layer containing silicon carbide is preferred.

Usually, the silicon carbide is doped with an element selected from the group of phosphorus, arsenic, antimony, boron, aluminium, gallium, indium, titanium, vanadium, chromium, manganese and mixtures thereof and/or the electrical properties of the silicon carbide are achieved by selective insertion of defect sites, in particular grid gaps, for example by treating the silicon carbide with high-energy electromagnetic radiation. Preferably, the silicon carbide is doped with elements of the 13th and 15th group of the periodic table of the elements, whereby in particular the electrical properties of the silicon carbide could be manipulated and adjusted in a targeted manner. Such doped silicon carbides are particularly suitable for applications in semiconductor technology.

If the silicon carbide is doped in the context of the present invention, it has proven useful if the doped silicon carbide contains the doping element in amounts of 0.000001 to 0.0005 wt. %, in particular 0.000001 to 0.0001 wt. %, preferably 0.000005 to 0.0001 wt. %, more preferably 0.000005 to 0.00005 wt. %, relative to the doped silicon carbide. Very small quantities of doping elements are thus completely sufficient for the specific adjustment of the electrical properties of the silicon carbide.

If a doping with phosphorus is to be carried out, it has proven to be best if a doping with phosphoric acid is used.

If arsenic or antimony is used for doping, it is recommended that the doping reagent is selected from arsenic trichloride, antimony chloride, arsenic oxide or antimony oxide.

If aluminium is to be used as a doping element, aluminium powder can be used as a doping agent, in particular for acidic or basic pH values. Furthermore, it is also possible to use aluminium chlorides. In general, when using metals as doping elements, chlorides, acetates, acetylacetonates, formates, alkoxides and hydroxides—with the exception of poorly soluble hydroxides—can always be used.

If boron is used as the doping element, the doping agent is usually boric acid.

If indium is used as the doping element, the doping reagent is usually selected from indium halides, especially indium trichloride (InCl₃).

If gallium is used as the dopant element, the doping reagent is usually selected from gallium halides, in particular GaCl₃.

If titanium, vanadium, chromium and/or manganese are used as doping elements, the corresponding metal chlorides are preferably used.

In addition, in another advantageous embodiment of the invention, the carbon- and silicon-containing solution or dispersion, in particular the SiC precursorsol, is applied as a layer, in particular as a homogeneous layer, to a carrier in the first method step (a). The carrier preferably contains silicon carbide, preferably 3C-SiC, and/or is n-doped. The carrier serves for mechanical stability during the curing of the carbon and silicon-containing solution or dispersion. In this process, the carbon- and silicon-containing solution or dispersion is applied to the carrier, wherein the carrier can also pass through all thermal treatment stages or is configured such that the carrier does not adversely affect the properties of the layer to be produced by the carbon- and silicon-containing solution or dispersion. Therefore, the carrier enables easy application of the carbon- and silicon-containing solution or dispersion and guarantees the mechanical stability of the layer to be produced.

The carbon- and silicon-containing solution or dispersion can be applied to the carrier by any suitable method. However, it has proven to be advantageous if in method step (a) the carbon- and silicon-containing solution or dispersion, in particular the SiC precursorsol, is applied by a coating process. The coating process can be dip coating, spin coating, spraying, rolling, pressing or printing. Particularly good results are obtained when the carbon and silicon-containing solution or dispersion, in particular the SiC precursorsol, is applied to the carrier by dip coating, spin coating, spraying or printing, preferably by dip coating.

As far as the thickness of the layer with which the carbon- and silicon-containing solution or dispersion, in particular the SiC precursorsol, is applied to the carrier is concerned, this can vary in a wide range depending on the intended use of the silicon carbide and the chemical composition of the silicon carbide. Usually, in method step (a), the carbon- and silicon-containing solution or dispersion, in particular the SiC precursorsol, is applied to the substrate with a layer thickness in the range from 0.1 to 1,000 μm, in particular 0.1 to 500 μm, preferably 0.1 to 300 μm, more preferably 0.1 to 10 μm. During the thermal treatment of the carbon- and silicon-containing solution or dispersion, a reduction of the layer height of the carbon- and silicon-containing solution or dispersion can be achieved. This reduction can be at least essentially 20% of the original layer thickness of the carbon- and silicon-containing solution or dispersion.

Furthermore, within the scope of the present invention, it may be provided that the carbon- and silicon-containing solution or dispersion, in particular the SiC precursorsol, has a Brookfield dynamic viscosity at 25° C. in the range of 3 to 500 mPas, in particular 4 to 200 mPas, preferably 5 to 100 mPas. If the carbon- and silicon-containing solution or dispersion, in particular the SiC precursorsol, has dynamic viscosities in the above-mentioned ranges, the layer density with which the silicon- and carbon-containing solution is applied, in particular to the carrier, can be varied in wide ranges. In particular, very high layer thicknesses can be achieved with a single application of the silicon- and carbon-containing solution, which is advantageous, for example, in the production of silicon carbide wafers, since the wafer can be accessed in only a few work steps.

According to a preferred embodiment of the present invention, the carbon- and silicon-containing solution or dispersion, in particular the SiC precursorsol, comprises

(A) at least one silicon-containing compound,

(B) at least one carbon-containing compound; and

(C) at least one solvent or dispersant.

In the context of the present invention, the silicon- and carbon-containing solution or dispersion, in particular the SiC precursorsol, comprises special precursors which release silicon under process conditions and special precursors which release carbon under process conditions. In this way, the ratio of carbon to silicon in the carbon- and silicon-containing solutions or dispersions can be easily adjusted and tailored to the respective application.

Particularly good results are obtained within the scope of the present invention if the silicon-containing compound is selected from silanes, silane hydrolysates, orthosilicic acid and mixtures thereof. Particularly preferred the silicon-containing compound is a silane.

Likewise, in the context of the present invention, it has proven to be advantageous if the carbon-containing compound is selected from the group of sugars, in particular sucrose, glucose, fructose, invert sugar, maltose; starch; starch derivatives; organic polymers, in particular phenol-formaldehyde resin and resorcinol-formaldehyde resin, and mixtures thereof.

As far as the ratio of silicon to carbon in the carbon- and silicon-containing solution or dispersion is concerned, this can naturally vary over a wide range. However, it has proved to be useful if the carbon- and silicon-containing solution or dispersion, in particular the SiC precursorsol, has a weight ratio of silicon to carbon in the range from 1:1 to 1:10, in particular 1:2 to 1:7, preferably 1:3 to 1:5, more preferably 1:3.5 to 1:4.5. Particularly good results are obtained within the scope of the present invention if the weight-related ratio of silicon to carbon in the carbon- and silicon-containing solution or dispersion, in particular in the SiC precursorsol, is 1:4. With the above-mentioned ratios of silicon to carbon, it is possible to produce silicon carbide monocrystals, in particular monocrystalline silicon carbide layers, in a targeted and reproducible manner, in particular in a subsequent thermal treatment.

As far as the selection of the solvent or dispersion agent is concerned, this can be chosen from all suitable solvents or dispersion agents. Usually, however, the solvent or dispersant is selected from water and organic solvents and their mixtures. In particular in the case of mixtures containing water, the usually hydrolysable or sovolysable starting compounds are converted to inorganic hydroxides, in particular metal hydroxides and silicas, which then condense so that precursors suitable for pyrolysis and crystallization are obtained.

Furthermore, the compounds used should have sufficiently high solubilities in the solvents used, in particular in ethanol and/or water, to be able to form finely divided dispersions of the solutions, in particular sols, and may not react with other components of the solution or dispersion, in particular the sol, to form insoluble compounds during the production process.

In addition, the reaction rate of the individual reactions must be coordinated with one another, since the hydrolysis, condensation and, if necessary, gelation of the composition according to the invention should, if possible, proceed undisturbed in order to obtain a distribution of the individual components in the sol that is as homogeneous as possible.

The reaction products formed must not be sensitive to oxidation and should also not be volatile.

Within the scope of the present invention, it may be provided that the organic solvent is selected from alcohols, in particular methanol, ethanol, 2-propanol, acetone, ethyl acetate and mixtures thereof. It is particularly preferred in this context if the organic solvent is selected from methanol, ethanol, 2-propanol and mixtures thereof, wherein ethanol is particularly preferred.

The organic solvents mentioned above are miscible with water in a wide range and are in particular suitable for the dispersion or dissolution of polar inorganic substances, such as metal salts.

As mentioned above, mixtures of water and at least one organic solvent, in particular mixtures of water and ethanol, preferably as solvents or dispersants, are used within the scope of the present invention. In this context, it is preferred if the solvent or dispersant has a weight-related ratio of water to organic solvent of 1:10 to 20:1, in particular 1:5 to 15:1, preferably 1:2 to 10:1, more preferably 1:1 to 5:1, particularly preferably 1:3. The ratio of water to organic solvents makes it possible, on the one hand, to adjust the rate of hydrolysis, in particular of the silicon-containing compound and the doping reagents, and, on the other hand, to adjust the solubility and reaction rate of the carbon-containing compound, in particular of the carbon-containing precursor compound, such as sugar, for example.

The amount in which the carbon- and silicon-containing solution or dispersion contains the solvent or dispersant can vary over a wide range depending on the respective application conditions and the type of doped or undoped silicon carbide to be produced. Usually, however, the carbon- and silicon-containing solution or dispersion contains the solvent or dispersant in quantities of 10 to 80 wt. %, in particular 15 to 75 wt. %, preferably 20 to 70 wt. %, preferably 20 to 65 wt. %, relative to the carbon- and silicon-containing solution or dispersion.

In the context of the present invention, it is usually provided that the carbon- and silicon-containing solution or dispersion has a weight-related ratio of silicon to carbon, in particular in the form of the silicon-containing compound and the carbon-containing compound, in the range from 1:1 to 1:10, in particular 1:2 to 1:7, preferably 1:3 to 1:5, more preferably 1:3.5 to 1:4.5. Particularly good results are obtained in this context if the carbon- and silicon-containing solution or dispersion has a weight-related ratio of silicon to carbon, in particular of silicon-containing compound to carbon-containing compound, of 1:4.

As far as the silicon-containing compound is concerned, it is preferred if the silicon-containing compound is selected from silanes, silane hydrolysates, orthosilicic acid and mixtures thereof, in particular silanes. Orthosilicic acid as well as the condensation products thereof can be obtained within the scope of the present invention, for example, from alkali silicates whose alkali metal ions have been exchanged for protons by ion exchange. Alkali metal compounds, however, are not used in the carbon- and silicon-containing solution or dispersion within the scope of the present invention, since they are also incorporated into the silicon carbide-containing compound. In the context of the present invention, alkali metal doping is generally not desired. If, however, it should be desired, suitable alkali metal salts, for example of the silicon-containing compounds or alkali phosphates, can be used.

If a silane is used as a silicon-containing compound in the context of the present invention, it has proven useful if the silane is selected from silanes of the general formula I

R₄₋ₙSiXₙ (I)

with
R=alkyl, in particular C1 to C5 alkyl, preferably C1 to C3 alkyl, preferably C1 and/or C2 alkyl;
   aryl, in particular C6 to C20 aryl, preferably C6 to C15 aryl, preferably C6 to C10 aryl;
   olefin, in particular terminal olefin, preferably C2 to C10 olefin, preferably C2 to C8 olefin, particularly preferably C2 to C5 olefin, particularly preferably C2 and/or C3 olefin, particularly preferably vinyl;
   amine, in particular C2- to C10-amine, preferably C2- to C8-amine, preferably C2- to C5-amine, particularly preferably C2- and/or C3-amine;
   carboxylic acid, in particular C2- to C10-carboxylic acid, preferably C2- to C8-carboxylic acid, preferably C2- to C5-carboxylic acid, particularly preferably C2- and/or C3-carboxylic acid;
   alcohol, in particular C2- to C10-alcohol, preferably C2- to C8-alcohol, preferably C2- to C5-alcohol, particularly preferably C2- and/or C3-alcohol;
X=halide, in particular chloride and/or bromide;
   alkoxy, in particular C1- to C6-alkoxy, particularly preferably C1- to C4-alkoxy, particularly preferably C1- and/or C2-alkoxy; and
n=1-4, preferably 3 or 4

However, particularly good results are obtained if the silane is selected from silanes of the general formula Ia

R₄₋ₙSiXₙ (Ia)

with
R=C1 to C3 alkyl, in particular C1 and/or C2 alkyl;
   C6 to C15 aryl, in particular C6 to C10 aryl;
   C2 and/or C3 olefin, in particular vinyl;
X=alkoxy, in particular C1 to C6 alkoxy, particularly preferably C1 to C4 alkoxy, particularly preferably C1 and/or C2 alkoxy; and
   n=3 or 4.

By hydrolysis and subsequent condensation reaction of the aforementioned silanes, condensed orthosilicic acids or siloxanes can be obtained in a simple manner within the scope of the present invention, which have only very small particle sizes, wherein further elements, in particular metal hydroxides, can also be incorporated into the basic structure.

By using carbon- and silicon-containing solutions or dispersions, in particular SiC precursorsols, it is possible within the scope of the present invention to arrange the components of the silicon carbide to be produced in homogeneous and fine distribution as spatially adjacent to one another as possible, so that when energy is applied, the individual components of the silicon carbide-containing target compound are in immediate proximity to one another and do not have to diffuse comparatively long distances first.

Particularly good results are obtained in the context of the present invention if the silicon-containing compound is selected from tetraalkoxy-silanes, trialkoxysilanes and mixtures thereof, preferably tetraethoxy-silane, tetramethoxysilane or triethoxymethylsilane and mixtures thereof.

As far as the quantities in which the carbon- and silicon-containing solution or dispersion contains the silicon-containing compound are concerned, these can also vary within a wide range depending on the respective application conditions. Usually, however, the carbon- and silicon-containing solution or dispersion contains the silicon-containing compound in quantities of 1 to 80 wt. %, in particular 2 to 70 wt. %, preferably 5 to 60 wt. %, more preferably 10 to 60 wt. %, relative to the carbon- and silicon-containing solution or dispersion.

As explained above, the carbon- and silicon-containing solution or dispersion according to the invention contains at least one carbon-containing compound. All compounds which can either be dissolved or at least finely dispersed in the solvents used and which can release solid carbon during pyrolysis are considered to be carbon-containing compounds. Preferably the carbon-containing compound is also capable of reducing metal hydroxides to elemental metal under process conditions.

In the context of the present invention, it has proven effective if the carbon-containing compound is selected from the group of sugars, in particular sucrose, glucose, fructose, invert sugar, maltose; starch; starch derivatives; organic polymers, in particular phenol-formaldehyde resin and resorcinol-formaldehyde resin, and mixtures thereof.

Particularly good results are obtained in the context of the present invention if the carbon-containing compound is selected from the group of sugars; starch, starch derivatives and mixtures thereof, preferably sugars, since the viscosity of the carbon- and silicon-containing solution or dispersion can be specifically adjusted, in particular by using sugars and starch or starch derivatives.

As far as the amount in which the carbon- and silicon-containing solution or dispersion contains the carbon-containing compound is concerned, this can also vary widely depending on the respective application and application conditions or the target compounds to be produced. Usually, however, the carbon- and silicon-containing solution or dispersion contains the carbon-containing compound in quantities of 5 to 50 wt. %, in particular 10 to 40 wt. %, preferably 10 to 35 wt. %, more preferably 12 to 30 wt. %, relative to the carbon- and silicon-containing solution or dispersion.

In the context of the present invention, the carbon- and silicon-containing solution or dispersion thus optionally contains a doping reagent. If the carbon- and silicon-containing solution or dispersion contains a doping reagent, the carbon- and silicon-containing solution or dispersion usually contains the doping reagent in amounts of 0.000001 to 15 wt. %, in particular 0.000001 to 10 wt. %, preferably 0.000005 to 5 wt. %, more preferably 0.00001 to 1 wt. %, based on the solution or dispersion. The properties of the resulting silicon carbide can be decisively changed by the addition of doping reagents.

Furthermore, it may be provided within the scope of the present invention that the carbon- and silicon-containing solution or dispersion, in particular the SiC precursorsol, contains doping reagents. Especially for applications in semiconductor technology, doping of the silicon carbide is common in order to produce semiconductor properties in the silicon carbide material, as described above. However, pure silicon carbide can be used as an insulator, for example.

According to a preferred embodiment of the present invention, the carbon and silicon-containing solution or dispersion, in particular the SiC precursorsol, comprises

(A) at least one silicon-containing compound,

(B) at least one carbon-containing compound,

(C) at least one solvent or dispersant; and

(D) optionally doping reagents.

As far as the carrier on which the silicon- and carbon-containing solution or dispersion, in particular the SiC precursorsol, is applied is concerned, this can be selected from a variety of suitable materials. In the context of the present invention it is possible that the carrier is selected from crystalline and amorphous carriers. According to a preferred embodiment of the present invention, the carrier is an amorphous carrier. It is a special feature of the present invention that the production of the silicon carbide layers does not have to be carried out exclusively on crystalline, in particular monocrystalline, carriers, but that also significantly cheaper amorphous carriers can be used.

With regard to the material of which the carrier is made, particularly good results are obtained when the material is selected from carbon, in particular graphite, and ceramic materials, in particular silicon carbide, silicon dioxide, aluminium oxide as well as metals and their mixtures.

However, particularly good results are obtained in the context of the present invention if the material of the carrier is carbon, in particular graphite. In particular by using graphite carriers, thin layers of silicon carbide or silicon carbide wafers can be produced very easily and cost-effectively with the method according to the invention. In addition, other suitable materials and carrier materials are, for example, silicon oxide, in particular silicon dioxide wafers, aluminium oxide, for example in the form of sapphire, as well as metals or metallized surfaces consisting of monocrystalline materials, in particular silicon carbide or silicon dioxide wafers, onto which a metal, for example platinum, has been vapour-deposited.

According to another preferred design, the substrate has a layer thickness of 1 to 1,000 μm, preferably of 1 to 300 μm, more preferably of 80 to 120 μm, and in particular at least substantially 100 μm. A carrier layer thickness of the above-mentioned type ensures the mechanical stability of the carbon- and silicon-containing solution or dispersion, in particular during thermal treatment. At the same time, however, as little as possible of the material (in terms of weight and/or volume) is used for the carrier. The aforementioned layer thicknesses of the carrier apply in particular to carriers which are not removed again after the production of the nitrogen-free silicon carbide layer. For carriers which are subsequently removed, such as carriers based on graphite, the layer thickness is less critical.

Within the scope of the present invention, it may also be provided that the carrier is removed after the thermal treatment, in particular after method step (b).

If the carrier is removed in the context of the present invention, it has proven to be useful if the carrier is removed oxidatively. Usually the carrier is removed thermally or chemically, in particular removed thermally or chemically by oxidation. In this context, particularly good results are obtained when the carrier is removed in an oxygen atmosphere, by means of ozone and/or by the action of aqueous hydrogen peroxide solution. In oxidative removal in an oxygen atmosphere, the carrier is, so to speak, burned, which is particularly suitable for carriers based on graphite.

The removal of the carrier allows in particular the production of almost two-dimensional silicon carbide bodies but also of silicon carbide wafers.

In this context, the thickness of the layer or wafer is generally determined by the thickness of the liquid carbon- and silicon-containing solution or dispersion, in particular the SiC precursor sol.

To produce silicon carbide wafers of particularly large thickness, method steps (a) and (b) are repeated until a wafer of the desired thickness is obtained. In this way, monocrystalline silicon carbide wafers of almost any thickness can be easily obtained.

In accordance with a preferred embodiment of the present invention, method steps (a) and (b) are repeated, wherein different carbon- and silicon-containing solutions or dispersions, in particular the SiC precursorsol, preferably with different doping reagents and/or different concentrations of doping reagents, are used in each pass. By using different carbon- and silicon-containing solutions or dispersions, in particular SiC precursorsols, when carrying out method steps (a) and (b), semiconductor materials with different electronic properties can be obtained which can be used as basic materials for electronic components. For example, layer sequences with pn doping for diodes and pnp or npn doping can be used as base materials for bipolar transistors. Also solar cells, in particular intermediate band solar cells based on silicon carbide, are accessible in this way as described below.

Further subject matter of the present invention—according to a second aspect of the present invention—is a SiC layer and/or a SiC wafer. In particular, the SiC layer and/or the SiC wafer is produced by a method of the type described above. The SiC layer and/or the SiC wafer comprises silicon carbide, preferably 3C-SiC. The SiC layer and/or the SiC wafer are characterized by the fact that the SiC layer and/or the SiC wafer are completely nitrogen-free.

According to a preferred embodiment of the present invention, the SiC layer and/or the SiC wafer is made of silicon carbide, which is optionally doped or specifically provided with defect sites, in particular empty lattice sites.

A nitrogen-free SiC layer and/or a nitrogen-free SiC wafer are thereby particularly suitable for semiconductor applications, for example if it is to be ensured that no contamination or doping with nitrogen is provided in a layer, in particular to avoid undesired recombination.

In order to avoid unnecessary repetition, reference is made to the previous explanations of the method for producing a nitrogen-free layer containing silicon carbide. In this context, the same also applies to a SiC-layer or a SiC-wafer.

In addition, another subject matter of the present invention—according to a third aspect of the present invention—is the use of a preferably p-doped SiC layer and/or a SiC wafer as described above and/or produced according to a method as described above in a solar cell, in particular in an intermediate band solar cell.

The nitrogen-free silicon carbide-containing layer according to the invention proves to be particularly advantageous, since a layer in a solar cell structure for the production of an intermediate band solar cell should be nitrogen-free and preferably doped with boron. In an intermediate band solar cell, the use of the nitrogen-free layer ensures that the intermediate band energy level is not shifted by nitrogen in a p-doped layer. This is a significant improvement over the state of the art, since although silicon carbide is theoretically particularly well suited for intermediate band solar cells due to the large band gap, it is inevitably contaminated with nitrogen. Since nitrogen is the flat dopant in silicon carbide, it is also electrically active. However, if an insulating silicon carbide layer is to be produced from a nitrogen-containing silicon carbide layer, the nitrogen is passivated with boron, as explained above. This leads to donor-acceptor recombination luminescence under sunlight, which should be avoided in any case. Only with the present invention it can be guaranteed that nitrogen-free silicon carbide can be made available in one layer.

In addition, a further subject-matter of the present invention—according to a fourth aspect of the present invention—is a method for producing a solar cell, in particular an intermediate band solar cell, with a layered structure, with at least one, in particular thin, nitrogen-free layer comprising silicon carbide, preferably 3C-SiC, in particular produced according to the method described above, wherein, for producing the nitrogen-free layer
(a) in a first method step, a liquid carbon- and silicon-containing solution or dispersion, in particular a SiC precursorsol, is applied to a carrier or a layer of the layered carrier,
(b) in a second method step following the first method step (a), the carbon- and silicon-containing solution or dispersion, in particular the SiC persecursol, is converted to silicon carbide, wherein the carbon- and silicon-containing solution or dispersion, in particular the SiC precursorsol, is subjected to a multi-stage thermal treatment, wherein
   (i) in a first thermal process stage (i) the carbon- and silicon-containing solution or dispersion, in particular the SiC precursorsol, is heated to temperatures of 300° C. or higher, in particular 300 to 1800° C., preferably 800 to 1000° C., and
   (ii) in a thermal process stage (ii) following the first thermal process stage (i), the carbon- and silicon-containing solution or dispersion, in particular the SiC precursorsol, is heated to temperatures of 1800° C. or higher, in particular 1800 to 2200° C.

With the nitrogen-free layer according to the invention, an intermediate band solar cell can be produced. This is a major step forward in the development of solar cells, as the efficiency of a conventional solar cell can be significantly increased by an intermediate band solar cell. Thus, an intermediate band solar cell can be provided which has up to 50% higher efficiency than conventional solar cells. To manufacture an intermediate band solar cell, a nitrogen-free layer obtained by a thermal heat treatment of a carbon- and silicon-containing solution or dispersion is used.

As explained above, an intermediate band solar cell requires a nitrogen-free layer, preferably within the p-doped layer, so that recombination luminescence due to passivation of nitrogen with boron can be avoided. As a result, the previously unavoidable short circuit of the solar cell can be bypassed.

With the method according to the invention, a commercially usable intermediate band solar cell can be made available, which was not accessible until now.

The use of a nitrogen-free layer in another solar cell form or solar cell structure is also conceivable in this connection, whereby the semiconductor properties and in particular the efficiency can be improved by the nitrogen-free layer, since an undesired contamination with nitrogen can be avoided.

As a result, a semiconductor material can be provided which can meet the material requirements for third generation solar cells. As already explained at the beginning, silicon carbide in particular offers a high development potential in the field of third-generation solar cells, which can now be implemented and used by the inventive method for producing a solar cell through the nitrogen-free layer. The previous restrictions on the material use of silicon carbide, in particular of cubic (3C-SiC) silicon carbide, can therefore be circumvented.

By means of the method according to the invention, a solar cell, in particular an intermediate band solar cell, can be produced with comparatively low manufacturing costs—even on a large industrial scale, wherein monocrystalline silicon carbide, which is also nitrogen-free in at least one layer, can be used.

Furthermore, not only the necessary nitrogen-free SiC layer can be ensured within the scope of the present invention, but also SiC layers, which are suitable for the production of solar cells, can be produced at low cost.

In principle, it is also conceivable to obtain at least one nitrogen-free layer after the thermal treatment described above and to apply further layers or a further layer to the nitrogen-free layer using a different process or to apply the nitrogen-free layer to a layer of the solar cell obtained by a different manufacturing process.

For further details on the method for producing a solar cell according to the invention, reference can be made to the above explanations on the production of a nitrogen-free layer, which also apply accordingly with regard to the method for producing a solar cell according to the invention.

It is understood that the above-mentioned and explained characteristics, in particular also taking into account the above-mentioned composition of the nitrogen-free layer, apply correspondingly to the process for manufacturing a solar cell. The advantages and special features described there can also be applied to the process for manufacturing a solar cell.

In the following, special features of the method for producing a solar cell are discussed which differ from the features of the method for producing a nitrogen-free layer containing silicon carbide or characterize it further.

In the context of the present invention, a carrier is understood to be any suitable carrier which gives the layer structure of the solar cell mechanical stability, in particular at least during the production of the layer structure. The carrier can form a part of the solar cell, i.e. it can be a part of the layered structure of the solar cell or, in the case of particularly mechanically resistant layers of the solar cell, it can be removed again after the layered structure or a part of the layered structure has been produced. If the substrate forms part of the solar cell, an electrically conductive and/or transparent substrate is used. An electrically conductive substrate can act as an electrode material, in particular as an anode material of the solar cell, or it can transmit the current generated by the photo-voltage to the actual electrode, for example a baffle plate or a metal layer. Metal substrates, graphite substrates and preferably heavily nitrogen-doped silicon carbide substrates can be used as electrically conductive substrates. Glass substrates are particularly suitable as transparent substrates, preferably quartz glass substrates, silicon carbide substrates or sapphire substrates.

The carrier described in the process for producing a nitrogen-free layer can in this context be a substrate which has the aforementioned properties of the carrier, wherein transparent and/or electrically conductive substrates are preferred for the production of the solar cell. In addition, the nitrogen-free layer can also be applied to a further layer, the further layer then serving as a carrier and having, for example, been previously applied to a substrate.

In this context, it should be noted that p-doping is preferred for doping the nitrogen-free layer. In particular, a doping by boron and/or aluminium and/or chromium and/or by vanadium and/or manganese and/or titanium and/or scandium is carried out. When boron is used as the doping element, it is preferable to use additives such as di-sodium tetraborate and/or boric acid.

Furthermore, it is also conceivable to produce grid gaps and/or so-called defects in the nitrogen-free layer, in particular by using high-energy radiation, preferably by electron irradiation. Due to the so-called empty lattice sites and/or voids, defects are present in the crystal which no longer contain an atom, wherein the atom may have been removed by high-energy radiation, preferably laser radiation. The aforementioned empty lattice sites can contribute to the semiconductor properties of the solar cell to be manufactured. Empty lattice sites, in particular Si or C voids, are preferably created by electron irradiation and can be converted by thermal processes into a large number of different defects—about 12 are known to date—with different optical and electrical properties, such as double empty sites, antisites, etc. These all have different optical properties, so that intermediate bands can be generated in a targeted manner. The energy of the radiation and the duration of exposure determine the concentration of the generated defects. If the concentration is sufficiently high, defect bands are formed which are suitable as intermediate bands. In the past, such processes and properties have been intensively investigated in basic research.

As layer thickness of the nitrogen-free layer, preferably in method step (a) the carbon- and silicon-containing solution or dispersion, in particular the SiC precursorsol, is applied with a layer thickness in the range of 1 nm to 100 μm, in particular 5 to 500 nm, preferably 8 to 300 nm, more preferably 10 to 200 nm. Layer thicknesses of 10 to 200 nm each are advantageous, but thicker layers, as described above for the process of producing a nitrogen-free layer, are also possible. The thickness of the layer can depend on the wetting and the, especially adjustable, viscosity of the precursorsol. If the layer thickness of the sol is chosen below 10 μm, a single-crystalline layer can be expected. In principle, however, all types of SiC surfaces, be they crystalline and/or amorphous, can also be coated.

In a further preferred embodiment of the present invention, an at least two-layer structure is applied, in particular to a carrier substrate, the at least two-layer structure having a further layer. This further layer, which in particular comprises silicon carbide, preferably 3C-SiC, can be produced by a method feature of the kind described above. Preferably the further layer is a silicon carbide layer, in particular a 3C-SiC layer, which is preferably n-doped, preferably with an element of the 15th group of the periodic table of the elements, preferably nitrogen and/or phosphorus.

Preferably, the further layer is first applied to the carrier and then the nitrogen-free layer is applied to the further layer.

In principle, it is also conceivable in this context to apply a further, preferably undoped, protective layer above the nitrogen-free layer, in particular where the undoped protective layer has been produced according to a previously described process feature. In particular, the protective layer has undergone a heat treatment. The undoped protective layer can have a layer thickness of 0.1 to 25 nm, preferably 1 to 10 nm.

In addition, the nitrogen-free layer can also be applied immediately to the further layer, at least in principle, whereby the pn transition can be influenced and the temperature treatment for adjacent layers can be carried out simultaneously.

Furthermore, it is also conceivable that the further layer is subjected to a temperature treatment which is separate or independent from the nitrogen-free layer. In this context, it is understood that if the nitrogen-free layer is applied to the further layer and/or the further layer is applied to the nitrogen-free layer, the other layer can also undergo the temperature treatment of the nitrogen-free layer and/or the further layer.

In addition, the further layer may be doped, preferably n-doped. An n-doping can be achieved preferably with nitrogen and/or phosphorus.

If the silicon carbide of the further layer is to be doped with nitrogen, nitric acid, ammonium chloride, potassium nitrate and/or melamine can be used as doping reagents. In the case of nitrogen, it is also possible to carry out the method for producing the further layer in a nitrogen atmosphere, whereby doping with nitrogen can also be achieved, but with less precision.

In addition, the further layer can also be subjected to a thermal treatment, in particular to produce a further layer containing monocrystalline silicon umcarbide. It may be provided that
(A) in a first thermal process stage, the solution or dispersion containing carbon and silicon, in particular the SiC precursorsol, is heated to temperatures in the range from 800 to 1,200° C., in particular 900 to 1,100° C., preferably 950 to 1,050° C., more preferably for 1 to 10 minutes, in particular preferably for 1 to 5 minutes and in particular at least substantially for 2 minutes, and
(B) in a second thermal process stage following the first thermal process stage (A), the carbon- and silicon-containing solution or dispersion, in particular the SiC precursorsol, is heated to temperatures of 1,800° C. or higher, in particular for 10 to 90 minutes, preferably for 10 to 40 minutes and in particular at least essentially for 30 minutes.

The temperature treatment described above can result in the formation of monocrystalline layers which may contain amorphous silicon carbide.

In addition, an electrically conductive layer, in particular a metal grid, can also be arranged above the nitrogen-free layer and/or the further layer. In this case, the electrically conductive layer can in particular be arranged away from the substrate and/or on the side of the solar cell opposite the substrate. The electrically conductive layer can serve as the cathode of the solar cell and, together with the existing back contact, can be used to pass on current. In this context, it is understood that further possibilities for contacting can also be used with the layer structure of the solar cell according to the invention. In principle, however, it is also conceivable in this context to use the contacting that is also usual for conventional solar cells. In accordance with a preferred embodiment, the electrically conductive layer, in particular the metal grid, is configured as an aluminium drainage network or made of aluminium. The electrically conductive layer, in particular the metal grid, can therefore be arranged or applied on the top layer of the solar cell, as is already known for conventional solar cells.

In a further development of the inventive idea, a reflective layer and/or an electrically conductive layer, in particular a metal layer and/or a TCO anode, can be arranged below the substrate and/or below the nitrogen-free layer and/or below the further layer. Preferably, the reflective layer and/or metal layer is arranged on the side of the solar cell opposite the metal grid, in particular the aluminium discharge grid. The abbreviation “TCO” in this context means “transparent conductive oxides”. TCOs are materials with a comparatively low adsorption of electromagnetic waves in the visible light range. Preferred TCO materials are indium tin oxide (ITO), fluorine tin oxide (FTO), aluminium tin oxide (AZO) and antimony tin oxide. The electrically conductive layer is used for contacting and transmitting the current generated by the solar cell or the charge carriers formed.

Furthermore, according to a fifth aspect of the present invention, another subject matter of the present invention is a solar cell, in particular an intermediate band solar cell. The solar cell is in particular produced according to the previously described process for the production of a solar cell, in particular using a SiC layer and/or a SiC wafer as described above and/or produced according to a method as described above. The solar cell has at least one layer containing silicon carbide. According to the invention, it is intended that the layer comprising silicon carbide is completely free of nitrogen.

To this preferred embodiment of the present invention, all advantages, features and special as well as preferred embodiments of the present invention can be equally applied.

In order to avoid unnecessary repetition, the advantages and features of the solar cell having at least one nitrogen-free layer are not described here.

In addition, another subject matter of the present invention—according to a sixth aspect of the present invention—is a process for the selective generation of energy levels between the valence band and the conduction band of a semiconductor by the selective generation of empty lattice sites in the semiconductor.

According to a preferred embodiment of the present invention, the generated energy levels between the valence band and the conduction band are in the form of a band, in particular an intermediate band.

In the context of the present invention, it is thus preferred if this aspect of the present invention is a method for the selective generation of intermediate bands between the valence band and the conduction band of a semiconductor by the selective generation of lattice gaps in the semiconductor.

This is because, as the applicant has surprisingly found out, energy levels and energy bands located between the valence band and the conduction band of the semiconductor material can be generated by selective generation of lattice gaps and resulting defect structures in a semiconductor material.

Usually the lattice gaps are generated by radiation, especially electron radiation. Particularly good results are obtained in this context when the energy of the radiation exceeds 2 MeV.

In the context of the present invention, it is furthermore preferred if, in a first process step, the semiconductor material is irradiated, in particular with electron radiation, whereby grid gaps are produced.

In a second process step following the first process step, defect structures are then produced from the grid lattice by thermal processes.

The defects or defect structures which can be generated from the gaps have different optical and electrical properties, such as double gaps, antisites etc. Since the different defects have different optical and electrical properties, intermediate bands can be generated in a semiconductor material.

The energy and exposure time of the radiation determine the concentration of the generated defects.

In the context of the present invention, it is furthermore preferred if the semiconductor consists of silicon carbide. In particular, it is preferred if the semiconductor is a previously described nitrogen-free silicon carbide layer.

Further features, advantages and possible applications of the present invention result from the following descriptions of execution examples based on the drawing and the drawing itself. All described and/or pictorially represented features, either individually or in any combination, form the subject-matter of the present invention, irrespective of their summary in the claims or their re-relation.

It is shown according to:

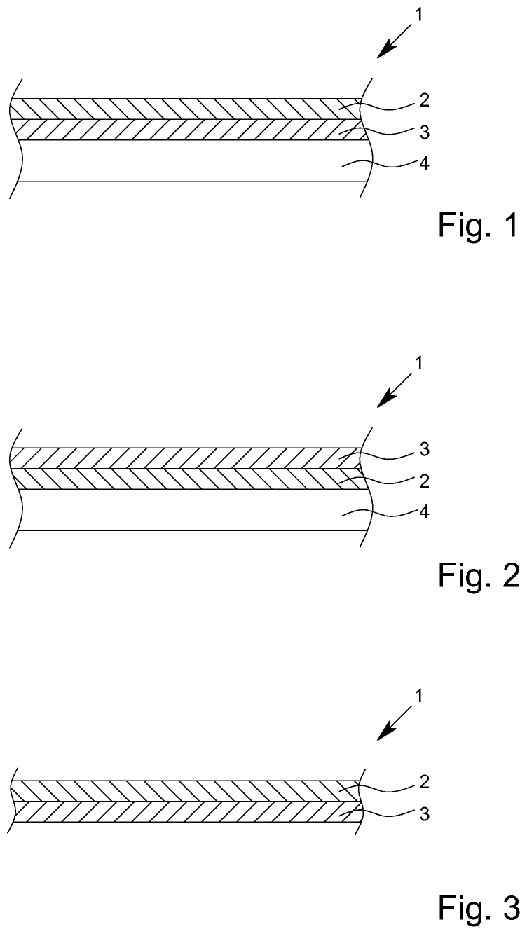

FIG. 1 a schematic representation of the layer structure of a solar cell according to the invention,

FIG. 2 a schematic representation of the layer structure of a further embodiment of a solar cell according to the invention,

FIG. 3 a schematic representation of the layer structure of a further embodiment of a solar cell according to the invention,

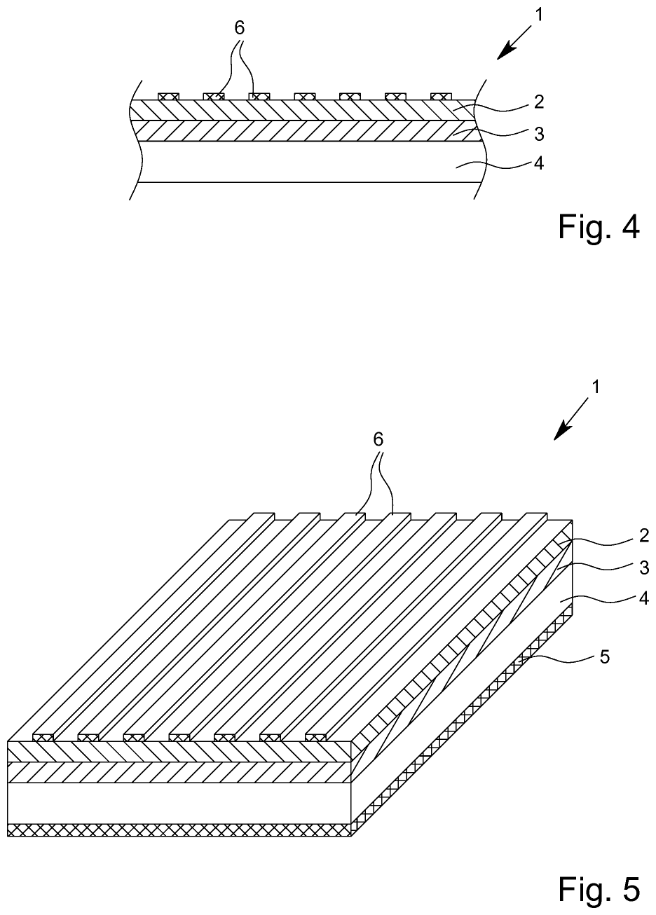

FIG. 4 a schematic representation of the layer structure of a further embodiment of a solar cell according to the invention,

FIG. 5 a schematic perspective representation of a further embodiment of a solar cell according to the invention and

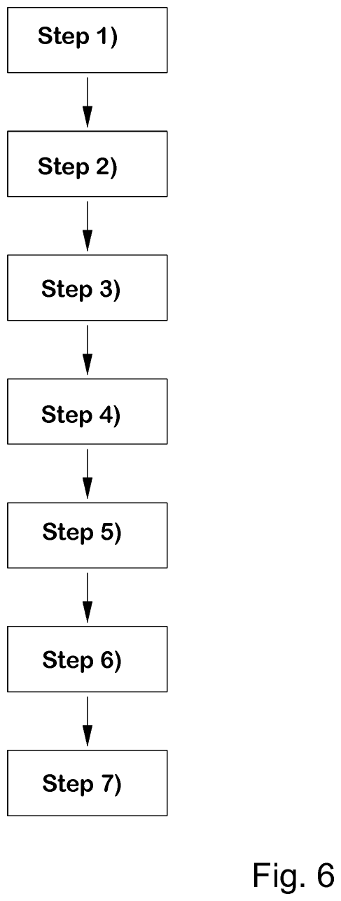

FIG. 6 a schematic representation of the process for producing a nitrogen-free layer as invented.

FIG. 1 shows a schematic layer structure of a solar cell 1, whereby the solar cell 1 has a carrier 4. Preferably, carrier 4 is a strongly nitrogen-doped silicon carbide or a transparent substrate, for example of quartz glass. A further layer 3 has been applied to carrier 4. On the further layer 3 a nitrogen-free layer 2 has been applied.

In the design example shown, carrier 4 has a layer density of at least essentially 100 μm. Furthermore, the carrier 4 is made of silicon carbide, which is also n-doped.

The other layer 3 and the nitrogen-free layer 2 have a layer thickness of at least essentially 100 nm. It is not shown that the further layer 3 has been applied to the carrier 4 by dip coating and the nitrogen-free layer 2 has been sprayed on. Furthermore, the nitrogen-free layer 2 is p-doped. Boron is used as the dopant for the nitrogen-free layer in the example shown. The other layer 3 is n-doped. The other layer 3 is doped with nitrogen. Accordingly, the further layer 3 has nitrogen, whereas the nitrogen-free layer 2 is completely nitrogen-free. In the example shown, both the further layer 3 and the nitrogen-free layer 2 have silicon carbide as material.

Furthermore, FIG. 2 shows another possible layer structure of the solar cell 1, where the nitrogen-free layer 2 has been applied to the carrier 4, while the nitrogen-free layer 2 serves as a carrier for the further layer 3. The further layer 3 and the nitrogen-free layer 2 have the material composition that has already been explained in the design example in FIG. 1.

FIG. 3 shows that after the layered structure of the solar cell 1 has been produced, the carrier 4, which previously served as a carrier for the further layer 3, can be removed.

Furthermore, FIG. 4 shows that an electrode, in particular a metal grid 6, can be arranged on top of the solar cell 1, i.e. in the present case on top of the nitrogen-free layer 2 and thus on the side of the solar cell 1 opposite the carrier 4. In the example shown, the metal grid 6 is configured as an aluminum drainage grid. The aluminium grid is used for contacting the solar cell 1.

FIG. 5 also shows that a further electrically conductive layer 5, in particular a metal layer or a TCO anode, can be arranged on the side of the solar cell 1 facing away from the metal grid 6. In other embodiments a mirror coating can be provided instead of and/or in addition to the electrically conductive layer. In the example shown, a TCO anode is provided as electrically conductive.

What is not shown is that in addition to the nitrogen-free layer 2 and the further layer 3, a protective layer, preferably undoped, can be provided, which can be arranged below and/or above layers 2, 3, for example.

The solar cell 1 shown in FIG. 5 is designed as a so-called intermediate band solar cell, whereby it uses an intermediate band energy level (“intermediate band”) between the conduction and valence band to increase the efficiency of solar cell 1. In this context, it is essential that the nitrogen-free layer 2 does not contain nitrogen. In the nitrogen-free layer 2, the material used is 3C-SiC, which is suitable for use within an intermedia band solar cell due to its large band gap.

Furthermore, according to an embodiment of the solar cell 1 not shown in the figure, it is possible that the solar cell has a transparent substrate 4, in particular a quartz glass substrate, on which the electrically conductive layer 5 is applied, in particular in the form of a TCO anode. An n-doped further layer 3, in particular an n-doped silicon carbide layer, is applied to the electrically conductive layer 5. The further silicon carbide layer is preferably n-doped with nitrogen or phosphorus. The nitrogen-free layer 2, which is p-doped, is applied to the further layer, in particular by using boric acid. An electrode, in particular a cathode, in the form of an aluminium grid is then applied to the nitrogen-free layer 2. Furthermore, it is possible that one or more protective layers, in particular based on silicon carbide, are applied to the electrode.

FIG. 6 shows a schematic representation of the method for producing a nitrogen-free layer 2. In step (1), the nitrogen-free layer 2 is applied to a carrier. Possible methods of application include printing, dipping, spin coating, dip coating, spraying, rolling or pressing. Preferably, the nitrogen-free layer 2 is applied to the substrate by dipping in step (1). Here, the nitrogen-free layer 2 is initially provided as a carbon- and silicon-containing solution or dispersion, especially SiC precursorsol.

In step (2), the carbon- and silicon-containing solution or dispersion is heated for drying and/or preheating to a temperature of at least substantially 200° C. for 15 minutes.

In steps (3) to (5) the carbon- and silicon-containing solution or dispersion is converted to silicon carbide, a thermal treatment being provided for this conversion. If necessary, the carbon- and silicon-containing solution and dispersion may contain doping reagents.

In step (3), in a first thermal process stage (i) it is provided that the carbon- and silicon-containing solution or dispersion is heated to 900° C. for 60 minutes.

In addition, step (4) provides that the carbon- and silicon-containing solution, in particular the glass obtained from step (3), is cooled, preferably quenched.

In step (5), in a second thermal process stage (ii), the carbon- and silicon-containing solution or dispersion is heated to at least substantially 2000° C. for at least substantially 40 minutes.

In addition, the process for the production of a nitrogen-free layer 2 described above provides for a doping of the nitrogen-free layer 2. Doping of the nitrogen-free layer 2 is preferably effected by using a solution or dispersion containing boric acid and carbon and nitrogen. However, it is also possible to adjust the electrical properties of the nitrogen-doped layer 2 by the targeted generation of grid gaps, for example by irradiation with high-energy electromagnetic radiation in step (6).

In step (7) the carrier 4 or substrate can be removed from the nitrogen-free layer 2.

In further process steps it may be provided that a further layer 3 and/or a protective layer, preferably undoped, can be applied to the nitrogen-free layer 2. In addition, the nitrogen-free layer 2 can also be applied to the further layer 3 and/or to the protective layer, preferably undoped. In this case, the aforementioned layers and/or a substrate can serve as a carrier 4 for depositing the carbon- and silicon-containing solution or dispersion for producing the nitrogen-free layer 2.

It is also intended that in step (1) the carbon- and silicon-containing solution or dispersion is applied with a layer thickness of 10 μm. The application is carried out in such a way that a homogeneous layer, in particular of the SiC precursor sol, is formed on the substrate.

Furthermore, it is also intended that crystalline silicon carbide is obtained from the carbon- and silicon-containing solution or dispersion by the thermal treatment in steps (3) and (5), whereby a glass is obtained in step (3). Accordingly, step (3) provides that the carbon- and silicon-containing solution or dispersion is converted into a glass.

The thermal treatment in step (3) is carried out at such a temperature or for such a long time that it can be ensured that all nitrogen-containing compounds have been decomposed by the temperature treatment, whereby the nitrogen-containing compounds can be transferred into the gas phase so that the nitrogen-free layer 2 obtained from the carbon- and silicon-containing solution or dispersion has the properties of a nitrogen-free layer 2.

### REFERENCE SIGNS

1 Solar cell
2 Nitrogen-free layer
3 Further layer
4 Carrier
5 Electrically conductive layer
6 Metal grid

1-20. (canceled)

21. A method for producing a silicon carbide-containing layer, the layer being nitrogen-free, wherein
(a) in a first method step, a liquid carbon- and silicon-containing solution or dispersion, in particular a SiC precursorsol, is applied to a carrier,
(b) in a second method step following the first method step (a), the carbon- and silicon-containing solution or dispersion, in particular the SiC precursorsol, is converted to silicon carbide, wherein the carbon- and silicon-containing solution or dispersion is subjected to a multi-stage thermal treatment, wherein
(i) in a first thermal process stage (i) the carbon- and silicon-containing solution or dispersion, in particular the SiC precursorsol, is heated to temperatures of 300° C. or higher, in particular 300 to 1800° C., preferably 800 to 1000° C., and
(ii) in a second thermal process stage following the first thermal process stage (i), the carbon- and silicon-containing solution or dispersion, in particular the SiC precursorsol, is heated to temperatures of 1800° C. or higher, in particular 1800 to 2200° C.

22. Method according to claim 21, characterized in that the thermal process stage (i) is carried out for at least about 5 to 150 minutes, and/or that the thermal process stage (ii) is carried out for at least about 10 to 90 minutes.

23. Method according to claim 21, characterized in that in a process stage preceding the first thermal process stage (i) the carbon- and silicon-containing solution or dispersion, in particular the SiC precursorsol, is heated to temperatures in the range of from 50 to 800° C., for at least substantially 5 to 30 minutes.

24. Method according to claim 21, characterized in that in process stage (i) nitrogen-containing compounds contained in the carbon- and silicon-containing solution or dispersion . . . the SiC precursorsol . . . are decomposed and/or transferred into the gas phase, wherein all nitrogen-containing compounds are decomposed by the temperature treatment, and transferred into the gas phase.

25. Method according to claim 21, characterized in that in process stage (i) the carbon- and silicon-containing solution or dispersion . . . the SiC precursorsol . . . is converted into a glass.

26. Method according to claim 25, characterized in that in process stage (ii) the glass obtained in process stage (i), is converted into crystalline silicon carbide.

27. Method according to claim 21, characterized in that a dopant is added to the SiC precursorsol.

28. Method according to claim 21, characterized in that for the first method step (a), the carbon- and silicon-containing solution or dispersion . . . the SiC precursorsol . . . is applied as a layer, in particular as an homogeneous layer, to a carrier selected from the group consisting of a silicon carbide-comprising carrier, a 3C-SiC-comprising carrier, and an n-doped, carrier.

29. Method according to claim 21, characterized in that in method step (a) the carbon- and silicon-containing solution or dispersion . . . the SiC precursorsol . . . is applied to the carrier by a coating process selected from the group consisting of dip coating, spin coating, spraying, rolling, pressing, and printing.

30. Method according to claim 21, characterized in that in method step (a) the carbon- and silicon-containing solution or dispersion . . . the SiC precursorsol . . . is applied to the carrier as a layer having thickness in the range from 1 μm to 1,000 μm.

31. Method according to claim 21, characterized in that the material of the carrier is selected from the group consisting of carbon, ceramic materials, mineral materials and metals.

32. Method according to claim 31, characterized in that the material of the carrier is selected from the group consisting of graphite, silicon carbide, silicon dioxide, corundum, sapphire, aluminium oxide, steel, and mixtures thereof.

33. Method according to claim 31, characterized in that after the thermal treatment, the carrier is removed.

34. A silicon carbide layer, produced by a method according to claim 21, wherein the silicon carbide layer consists of a silicon carbide layer selected from the group consisting of a SiC layer and a 3C-SiC layer,
wherein,
the silicon carbide layer or wafer is completely nitrogen-free.

35. Method for producing a solar cell, in particular an intermediate band solar cell having a layered structure with at least one, thin, nitrogen-free layer comprising silicon carbide, produced according to a method according to claim 21 wherein, in order to produce the nitrogen-free layer,
(a) in a first method step, a liquid carbon- and silicon-containing solution or dispersion, in particular a SiC precursorsol, is applied to a carrier or a layer of the layered carrier,
(b) in a second method step following the first method step (a), the carbon- and silicon-containing solution or dispersion, in particular the SiC precursorsol, is converted to silicon carbide, wherein the carbon- and silicon-containing solution or dispersion, in particular the SiC precursorsol, is subjected to a multi-stage thermal treatment, wherein
(i) in a first thermal process stage (i) the carbon- and silicon-containing solution or dispersion, in particular the SiC precursorsol, is heated to temperatures of 300 to 1800° C., and
(ii) in a second thermal process stage (ii) following the first thermal process stage (i), the carbon- and silicon-containing solution or dispersion, in particular the SiC precursorsol, is heated to temperatures of 1800 to 2200° C.

36. Method according to claim 35, characterized in that in method step (a) the carbon- and silicon-containing solution or dispersion, (the SiC precursorsol), is applied with a layer thickness in the range from 1 nm to 1,000 μm.

37. Method according to claim 35, characterized in that an at least two-layer structure is applied, wherein the at least two-layer structure has a further layer, comprising silicon carbide, produced according to at least one method feature according to claim 21.

38. Method according to claim 27, characterized in that first the further layer is applied to the carrier and then the nitrogen-free layer is applied to the further layer.

39. Method according to claim 37, characterized in that the further layer is doped, preferably n-doped, in particular by nitrogen and/or phosphorus.

40. An intermediate band solar cell, produced according to claim 35,
including a SiC layer or wafer with at least one layer comprising silicon carbide, preferably 3C-SiC,
wherein,
the at least one layer is completely free of nitrogen.
